(19) United States
(12) Patent Application Publication
(10) Pub. No.: US 2023/0324453 A1
(43) Pub. Date: Oct. 12, 2023

(54) MITIGATING AN INFLUENCE OF A MISMATCH LOSS IN A MEASUREMENT SETUP

(71) Applicant: Advantest Corporation, Tokyo (JP)

(72) Inventors: Matthias BURCZYK, Stuttgart (DE); Andy RICHTER, Gäufelden (DE)

(21) Appl. No.: 18/335,703

(22) Filed: Jun. 15, 2023

Related U.S. Application Data
(63) Continuation of application No. PCT/EP2021/085114, filed on Dec. 9, 2021.

(51) Int. Cl. G01R 31/28; G01R 35/00

(52) U.S. Cl. CPC G01R 31/2834; G01R 35/005

(57) ABSTRACT

Embodiments provide an apparatus including at least one of at least one transmission line or a phase shifting device. Further, the apparatus includes a measurement device operable to couple to a signal source via the at least transmission line to receive from the signal source a first signal comprising at least a first frequency. The measurement device is operable to output a measurement result based on the received first signal. The at least one transmission line and the phase shifting device are operable to induce a respective phase shift to the first signal. Also, the apparatus includes a measurement processing component operable to average a first measurement result and a second measurement result to generate a processed measurement result related to the first signal to mitigate an influence of a mismatch loss in a measurement setup environment.

### CROSS-REFERENCE TO RELATED APPLICATION

This application is a continuation of copending International Application No. PCT/EP2021/085114, filed Dec. 9, 2021, which is incorporated herein by reference in its entirety.

### TECHNICAL FIELD

Embodiments according to the disclosure are related to electronic circuits, automated test equipments, methods and computer programs for mitigating an influence of a mismatch loss in a measurement setup. Further embodiments according to the disclosure are related to concepts for mitigating mismatch loss uncertainties in a measurement setup. Further embodiments according to the disclosure are related to an automated test equipment (ATE) for mitigating an influence of a mismatch loss in a measurement setup and a method for mitigating an influence of a mismatch loss in a measurement setup, as well as to a computer program for performing said method. Further embodiments of the disclosure are related to mismatch error correction with phase offset frequency responses.

### BACKGROUND OF THE DISCLOSURE

The mismatch loss describes the amount of power of a high frequency system that will not be available on the output of the system because of impedance mismatches and signal reflections. Reflections occur when a transmission line in a high frequency system are not terminated with the characteristic impedance of the transmission line. In many applications, such an appropriate termination may not be possible or may only be achievable in an approximate manner.

Therefore, it is desired to get a concept for mitigating mismatch loss uncertainties, which makes a better compromise between the magnitude of the mismatch loss reduction and the complexity and costs in order to achieve such an improvement.

This is achieved by the subject matter of the independent claims of the present application.

Further embodiments according to the disclosure are defined by the subject matter of the dependent claims of the present application.

### SUMMARY OF THE DISCLOSURE

Embodiments according to the disclosure comprise an automated test equipment (ATE) for mitigating an influence of a mismatch loss in a measurement setup. The setup comprises a signal source, a measurement device, and a first transmission line, wherein the first transmission line is configured to couple the signal source and the measurement device, and wherein the signal source is configured to provide a first, e.g. radio frequency, signal comprising at least a first frequency, e.g. comprising a signal component with the first frequency, for the measurement device. The measurement setup may, for example, be a self-test setup and/or a self-calibration setup.

Additionally, the measurement setup may have a measurement processing component operable to average a first measurement result and a second measurement result to generate a processed measurement result related to the first signal to mitigate an influence of a mismatch loss in a measurement setup environment. The measurement processing component may be separate from the ATE or may be integrated into the ATE.

Furthermore, the measurement processing component and/or the automated test equipment (ATE) and is configured to average, e.g. to perform an averaging of, a first measurement result and a second, e.g. frequency response, e.g. scalar frequency response, measurement result, e.g. an amplitude or e.g. a power, in order to obtain a processed measurement result, e.g. a power measurement result or a level measurement result and/or e.g. a processed measurement result in which the influence of the mismatch loss is reduced by the averaging. The averaging may, for example, be a weighted averaging, in other words, the averaging may be or might be weighted. As an example, in a default averaging, the weights may all be equal to one, e.g. performing a normal averaging. However, differing weight values may also be chosen. In other words, according to embodiments, the averaging might be weighted, but by default it may, for example, be normal averaging.

Moreover, the first measurement is performed, e.g. via the measurement device, when the signal source, while providing the first, e.g. radio frequency, signal for the measurement device, and the measurement device are coupled with the first transmission line.

In addition, the second measurement is performed, e.g. via the measurement device, when the signal source, while providing the first, e.g. radio frequency, signal for the measurement device, and the measurement device are coupled with a second transmission line, wherein the second transmission line is configured to induce a phase shift to the first, e.g. radio frequency, signal at least for the first frequency of the signal, or when the signal source and the measurement device are coupled with the first transmission line and a phase shifting device, wherein the phase shifting device is configured to induce a phase shift, e.g. an additional phase shift, in addition to the phase shift caused by the first transmission line, to the first, e.g. radio frequency, signal at least for the first frequency of the signal, such that a phase shift between the source and the measurement device, which is, as an example, caused by the first transmission line and by the second transmission line, or, as another example, by the combination of the first transmission line and the phase shifting device, respectively, differs by a phase offset between the first measurement and the second measurement at least for the first frequency.

Embodiments according to the disclosure are based on the idea to mitigate an influence of a mismatch loss by averaging two measurement results, wherein the measurements are performed with different phase shifts between source and measurement device. The inventors recognized that an averaging of the measurement results with such an induced phase offset allows to mitigate or for example allows to cancel out the influence of the unknown phase relation of the reflections coefficients of signal source and measurement device. Reflections may, for example, be caused by impedance mismatches and signal reflections between signal source and measurement device.

It has been recognized that propagating waves on the transmission line, coupling signal source and measurement device, may be subject to multiple reflections. Hence, the reflection coefficients of the signal source and of the measurement device may have a significant impact on the power received by the measurement device and therefore the mismatch loss.

It has been recognized that a significant problem in the determination of said losses may be the unknown phase relation between the reflections coefficients. The inventors recognized that mismatch losses or mismatch errors, for example residual mismatch errors, may be mitigated by reducing or mitigating the influence of the phase relation of the reflections coefficients, and that this can be achieved by performing the two measurements with the phase offset and by averaging the measurement results.

As an example, an advantageous choice of the phase offset may allow to, for example at least partially, to eliminate or to mitigate to or remove the influence of the, for example unknown, phase relation of the reflection coefficients, for example by determining said influence, for example in order to perform a calibration based on the determined influence.

It has been found that the measurements may be performed using a signal with a first frequency, while changing or alternating the characteristics of the transmission line between the signal source and the measurement device. As a first option, the second measurement may be performed using the same or an equal or an equivalent signal from the signal source and a second transmission line, the second transmission line having, as an example, a different length than the first transmission line, in order to induce the phase offset in comparison to the first transmission line. As a second option, the second measurement may be performed using the same or equal or equivalent signal from the signal source, and the first transmission line and a phase shifting device. The phase shifting device may be configured to induce the phase offset in comparison to the first transmission line (or in comparison to the first measurement setup) for the first signal. Optionally a different transmission line may be used together with a phase shifting device, wherein the different transmission line and the phase shifting device together provide for a desirable or advantageous phase offset in comparison to the first transmission line (or in comparison to the first measurement setup).

Thus, it has been found that a measurement error caused by a mismatch loss may be significantly mitigated with relative small effort, e.g. without having a knowledge about an actual phase of a reflection coefficient of the signal source and/or of the measurement device. Rather, it has been recognized that an averaging of two measurement results (e.g. of levels or powers received at the measurement device), obtained using two different phase shifts between the signal source and the measurement device, brings along a significant improvement of the reliability of the measurement results (at least in a statistical sense). Also, it has been found that two different phase shifts between signal source and measurement device can be achieved in a relatively simple and cost-efficient manner.

As an example, the mismatch loss may be always there and unknown. With the inventive approach one can, for example, calculate (e.g. more or less, e.g. approximately) the correct value, which would be measured if the mismatch loss is, or for example was, not existing. Therefore, one may, for example in some cases, not be able to, or one can, for example in some cases, not state a mismatch loss mitigation. However, using embodiments of the disclosure, a person skilled in the art may, e.g. actually, mitigate the effect of it (e.g. the mismatch loss), or the uncertainty of it.

According to further embodiments of the disclosure, the automated test equipment is configured to determine a calibration information for the measurement device based on the averaging of the first measurement result and the second, e.g. frequency response, e.g. scalar frequency response, measurement result, e.g. based on the processed measurement result.

As an example, a signal source may be calibrated with sensors, for example thermal power sensors, for a specific impedance. Based on the signal source, for example a stimulus path, the measurement device may be calibrated. Hence a calibration may be valid only in a system with the specific impedance, e.g. a 50-Ohm system. However, this requirement may not always, or even often, be fulfilled. A matching of the signal source and the measurement device may be moderate or even bad. Therefore a mismatch error may be present. A calibration performed with such setup may therefore result in erroneous calibration data.

Hence, the calibration error may be mitigated using the inventive approach. Calibration data may be improved using the averaging of the two measurements, reducing the influence of an unknown phase relation between the reflection coefficients of the source and the measurement device, by introducing the phase offset. Hence, calibration may be improved even in systems without matching or well matching impedances.

According to further embodiments of the disclosure, the Automated Test Equipment (ATE) comprises the signal source and the measurement device, and the ATE is configured to use the calibration information to self-calibrate the measurement device, wherein, for example, the signal source of the measurement device is calibrated using a power meter, which may, for example be an external power meter (e.g. comprising a thermal power sensor), and which may, for example comprise a reflection factor which is smaller than −10 dB or smaller than −dB or smaller than −20 dB, before coupling the signal source to the measurement device.

It may be advantageous for certain applications to provide a complete testing system, hence according to embodiments, the ATE may comprise the signal source and/or the measurement device. As an example the ATE may only comprise the signal source or only the measurement device. However the ATE may as well comprise both. As an example, with a calibration performed as explained before, the ATE may self-calibrate the measurement device. Therefore, a test equipment with integrated calibration functionality may be provided.

According to further embodiments of the disclosure, the Automated Test Equipment (ATE) is configured to calibrate the signal source using a measurement result from an external power meter, before performing the self-calibration of the measurement device.

A well calibrated signal source may allow for a good calibration of the measurement device. Therefore, a signal source calibration in combination with the inventive calibration of the measurement device using the averaging may result in a highly accurate measurement setup.

According to further embodiments of the disclosure, the Automated Test Equipment (ATE) comprises the first transmission line and the second transmission line. Alternatively, the Automated Test Equipment comprises the first transmission line and the phase shifting device.

In addition, the Automated Test Equipment (ATE) is configured to change between a usage of the first transmission line and of the second transmission line between the signal source and the measurement device. Alternatively, the Automated Test Equipment (ATE) is configured to manipulate the phase shifting device, in order to induce the phase offset, e.g. to cause the difference of the phase shift between the source and the measurement device between the first measurement and the second measurement, at least for the first frequency.

Mitigation of the mismatch error may be fully, or partially, automated. As an example, switching of the first and second transmission line may be performed manually or automatically. Adaptation or manipulation or adjustment of the phase shifting device may as well be performed automatically. Hence, calibration or mitigation functionality may be automated. Hence, an automated test equipment may be provided with extensive inherent functionality.

According to further embodiments of the disclosure, the Automated test equipment is configured to determine, e.g. as the processed measurement result, an improved information about the first, e.g. radio frequency, signal of the signal source, e.g. an improved level information or an improved power information, based on the averaging of the first measurement result and the second, e.g. frequency response, e.g. scalar frequency response, measurement result.

Hence a calibration of the signal source may be performed and/or improved.

According to further embodiments of the disclosure, the Automated Test Equipment (ATE) comprises the measurement device and the signal source is a device under test (DUT) and the Automated Test Equipment (ATE) is configured to determine the output power of the device under test based on the averaging of the first measurement result and the second, e.g. frequency response, e.g. scalar frequency response, measurement result.

Furthermore, the ATE is configured to perform, e.g. as the first measurement, a first measurement of an output power of the device under test using the measurement device when the device under test is connected with the measurement device of the ATE via the first transmission line.

Moreover, the ATE is configured to perform, e.g. as the second measurement, a second measurement of an output power of the device under test using the measurement device when the device under test is connected with the measurement device of the ATE via the second transmission line, or via the first transmission line and the phase shifting device.

The signal source may, for example, be a device under test. Hence, in some applications it may be desirable to determine the output power of the device. On the one hand, the measurement device may not be calibrated or matched well. On the other hand, the device may, in addition, not be matched well. Hence, even in case the measurement device was perfectly calibrated, a mismatch error may occur. Therefore, mitigation of the mismatch error may be performed based on a first and second measurement by introducing a phase offset and by averaging the first and second measurement in order to mitigate the influence of the coupled reflections within the transmission line. Therefore, the output power of the device under test may be determined accurately.

According to further embodiments of the disclosure, the phase offset is 90° with a tolerance of +/−5° or +/−10° or +/−20° or +/−30°.

A phase offset of approximately 90° may provide good results regarding mismatch error mitigation. Averaging of the first and second measurement with a phase offset of approximately 90° may minimize or mitigate or weaken the influence of the unknown phase relation of the reflections coefficients.

According to further embodiments of the disclosure, the phase offset is larger than 15°, or larger than 30°, or larger than 45°, or larger than 60°.

The inventors recognized that an improvement, for example, with regard to calibration of signal source, e.g. device under test and/or measurement device may be achieved by the inventive method even with small phase offsets.

According to further embodiments of the disclosure, the signal source is configured to provide a second, e.g. radio frequency, signal comprising a second frequency, e.g. a signal comprising the first and second frequency, for the measurement device, wherein the second frequency is different from the first frequency. Furthermore, the Automated Test Equipment (ATE) is configured to average, e.g. to perform an averaging of, a third measurement result and a fourth, e.g. frequency response, e.g. scalar frequency response, measurement result, e.g. amplitude, e.g. power.

The third measurement is performed, e.g. via the measurement device, when the signal source, while providing the second, e.g. radio frequency, signal for the measurement device, and the measurement device are coupled with the first transmission line, and the fourth measurement is performed, e.g. via the measurement device, when the signal source, while providing the second, radio frequency, signal for the measurement device, and the measurement device are coupled with a third transmission line, wherein the third transmission line is configured to couple the signal source and the measurement device and wherein the third transmission line is configured to induce a phase shift to the second, e.g. radio frequency, signal at least for the second frequency of the signal, or when the signal source, while providing the second, radio frequency, signal for the measurement device, and the measurement device are coupled with the first transmission line and a phase shifting device, wherein the phase shifting device is configured to induce a phase shift, e.g. an additional phase shift, in addition to the phase shift caused by the first transmission line, to the second, e.g. radio frequency, signal at least for the second frequency of the signal, such that a phase shift between the signal source and the measurement device, which may for example be caused by the first transmission line and by the third transmission line, or by the combination of the first transmission line and the phase shifting device, respectively, differs by a phase offset between the first measurement and the third measurement at least for the second frequency.

In simple words, the averaging of measurements with phase offsets may be performed for different frequencies. In other words, according to embodiments of the disclosure, a mitigation of mismatch errors may be performed for different frequencies. The first transmission line may be used for the first and third measurement using the first and second signal comprising the first and respectively second frequency. For the second measurement, a predetermined phase offset may be introduced or induced using the first signal with the first frequency and for the fourth measurement a predetermined phase offset may be introduced or induced using the signal with the second frequency. As explained before, for the second and/or fourth measurement, the phase offset may be induced by using a different transmission line, e.g. a transmission line with different phase shifting characteristics or the same transmission line and a phase shifting device, in comparison to the first and respectively third measurement. Hence a mitigation of a mismatch error may be performed with respect to specific signal frequencies.

According to further embodiments of the disclosure, the Automated Test Equipment is configured to determine a calibration information for the measurement device based on the averaging of the first measurement result and the second measurement result, e.g. frequency response, e.g. scalar frequency response measurement result, and based on an averaging of the third measurement result and the fourth, e.g. frequency response, e.g. scalar frequency response, measurement result. Alternatively or in addition, the automated test equipment is configured to determine an improved information about the output power of the signal source based on the averaging of the first measurement result and the second measurement result, e.g. frequency response, e.g. scalar frequency response measurement result, and based on the averaging of the third measurement result and the fourth, e.g. frequency response, e.g. scalar frequency response, measurement result.

In addition to a frequency dependent mitigation of mismatch losses, calibration may as well be performed for different frequencies or frequency dependent. Calibration information may be used depending on a specific signal frequency. In between determined calibration data points for a specific frequency, interpolation may be used in order to provide calibration data for other frequencies.

According to further embodiments of the disclosure, the signal source is configured to provide a, e.g. radio frequency, signal comprising, e.g. simultaneously or sequentially, a plurality of different frequencies for the measurement device. In addition, the Automated Test Equipment (ATE) is configured to perform a plurality of averaging between a plurality of first measurement results of a plurality of first measurements and a plurality of second measurement results of a plurality of, e.g. frequency response, e.g. scalar frequency response, second measurements, e.g. amplitude, e.g. power.

Furthermore, the first measurements are performed for different frequencies, e.g. via the measurement device, when the signal source, while providing the, e.g. radio frequency, signal for the measurement device, and the measurement device are coupled with the first transmission line.

Moreover, the plurality of second measurements is performed for the different frequencies, e.g. via the measurement device, when the signal source, while providing the, e.g. radio frequency, signal for the measurement device, and the measurement device are coupled with the first transmission line and a phase shifting device.

In addition, the phase shifting device is configured to induce phase shifts, e.g. an additional phase shift, in addition to the phase shift caused by the first transmission line, to the signal for the plurality of frequencies, e.g. for a plurality of signal components having the plurality of frequencies, of the, e.g. radio frequency, signal.

The plurality of second measurements is performed, such that for each second measurement of the plurality of second measurements the signal comprises a respective phase shift between the signal source and the measurement device, induced by the phase shifting device, such that the respective phase shift differ by respective phase offsets, which may, for example, differ from frequency to frequency, or which may be at least approximately matched by the phase shifting device, between the second measurements and corresponding first measurements.

Averaging may be performed over a plurality of frequencies. With an increasing number of frequencies calibration or mismatch error corrections may be performed with increased accuracy. Moreover, frequency dependent correction data may be determined.

Further embodiments according to the disclosure comprise a method for mitigating an influence of a mismatch loss in a measurement setup, the measurement setup comprising a signal source, a measurement device, and a first transmission line. The measurement setup may, for example, be a self-test setup and/or a self-calibration setup. Furthermore, the method comprises coupling the signal source and the measurement device with the first transmission line, and providing, with the signal source, a first, e.g. radio frequency, signal comprising at least a first frequency, e.g. comprising a signal component with the first frequency, for the measurement device.

In addition, the method comprises performing a first measurement, e.g. via the measurement device, when the signal source, while providing the first, e.g. radio frequency, signal for the measurement device, and the measurement device are coupled with the first transmission line and coupling the signal source and the measurement device with a second transmission line, wherein the second transmission line is configured to induce a phase shift to the first, e.g. radio frequency, signal at least for the first frequency of the signal, or coupling the signal source and the measurement device with the first transmission line and a phase shifting device, wherein the phase shifting device is configured to induce a phase shift, e.g. an additional phase shift, in addition to the phase shift caused by the first transmission line, to the first, e.g. radio frequency, signal at least for the first frequency of the signal.

Moreover, the method comprises performing a second measurement, e.g. via the measurement device, when the signal source, while providing the first, radio frequency, signal for the measurement device, and the measurement device are coupled with the second transmission line, or with the first transmission line and the phase shifting device, such that a phase shift between the signal source and the measurement device, which is caused by the first transmission line and by the second transmission line, or by the combination of the first transmission line and the phase shifting device, respectively, differs by a phase offset between the first measurement and the second measurement at least for the first frequency.

The method further comprises averaging, e.g. to perform averaging of, a result of the first measurement and a result of the second, e.g. frequency response, e.g. scalar frequency response, measurement, e.g. amplitude, e.g. power, in order to obtain a processed measurement result, e.g. a power measurement result or a level measurement result; e.g. a processed measurement result in which the influence of the mismatch loss is reduced by the averaging.

The method as described above is based on the same considerations as the above-described automated test equipment. The method can be completed with all features and functionalities, which are also described with regard to the automated test equipment, individually or taken in combination.

Further embodiments according to the disclosure comprise a computer program for performing methods according to embodiments of the disclosure, when the program runs on a computer.

Further embodiments according to the disclosure comprise an electronic circuit for mitigating an influence of a mismatch loss in a measurement setup. The setup comprises a source, a measurement device, and a first transmission line, wherein the first transmission line is configured to couple the source and the measurement device. Furthermore, the source is configured to provide a first signal comprising at least a first frequency, for the measurement device and the electronic circuit is configured to average a first measurement result and a second measurement result, in order to obtain a processed measurement result. The measurement setup may, for example, be a self-test setup and/or a self-calibration setup.

The first measurement is performed when the signal source, while providing the first signal for the measurement device, and the measurement device are coupled with the first transmission line, and the second measurement is performed when the signal source, while providing the first signal for the measurement device, and the measurement device are coupled with a second transmission line, wherein the second transmission line is configured to induce a phase shift to the first signal at least for the first frequency of the signal, or when the signal source, while providing the first signal for the measurement device, and the measurement device are coupled with the first transmission line and a phase shifting device, wherein the phase shifting device is configured to induce a phase shift to the first signal at least for the first frequency of the signal, such that a phase shift between the source and the measurement device differs by a phase offset between the first measurement and the second measurement at least for the first frequency.

The electronic circuit may, for example, be a microchip, comprising, as an example, a transmitter system and/or a receiver system. Additionally or alternatively, the electronic circuit may comprise the measurement setup. Hence, the electronic circuit may, for example, be configured to perform an internal loopback test. Therefore, the signal source may, for example, be a transmitter system and the measurement device may, for example, be a receiver system and the transmitter system may, for example, be configured to provide the first signal to the receiver system. In order to provide the first and second measurement, the electronic circuit may, for example, comprise the first and second transmission line and/or the first transmission line and the phase shifting device.

According to further embodiments of the disclosure, the electronic circuit may, for example, be configured to perform an external loopback test. Therefore, the electronic circuit may, for example, be configured to provide the first signal, provided by the transmitter system, to the receiver system, using external first and/or second transmission lines and/or an external first transmission line and an external phase shifting device.

As another example, the electronic circuit may, for example be an automated test equipment or a component of an automated test equipment. Optionally, the electronic circuit may, for example, be a processing unit of a microchip.

This summary is provided to introduce a selection of principles of the disclosure in a simplified form that are further described below in the Detailed Description section. This summary is not intended to identify key features or essential features of the claimed subject matter, nor is it intended to be used to limit the scope of the claimed subject matter.

### BRIEF DESCRIPTION OF THE DRAWINGS

The accompanying drawings, which are incorporated in and form a part of this specification, illustrate embodiments, together with the description, serve to explain the principles of the disclosure.

Embodiments of the present disclosure are set out below in the figures.

The drawings are not necessarily to scale, emphasis instead generally being placed upon illustrating the principles of the disclosure. In the following description, various embodiments of the disclosure are described with reference to the following drawings.

FIGS. 1a, 1b, and 1c show a schematic view of an automated test equipment for mitigating an influence of a mismatch loss in a measurement setup according to embodiments of the disclosure.

FIG. 2 shows a schematic view of an automated test equipment for mitigating an influence of a mismatch loss in a measurement setup with additional, optional features, according to embodiments of the disclosure.

FIG. 3 shows a block diagram of a method, for mitigating an influence of a mismatch loss in a measurement setup, according to embodiments of the disclosure.

FIG. 4 shows a schematic example of a first RF (radio frequency) component and a second RF component connected together, according to embodiments of the disclosure.

FIG. 5 shows a schematic example of two measurement setups that may be used to perform the first and second measurement according to embodiments of the disclosure.

FIG. 6 shows an example of uncertainty limits in dB over different ρ_{G}ρ_{L}, according to embodiments of the disclosure.

FIG. 7 shows a part of the example shown in FIG. 6.

FIG. 8 shows an example of a receiver accuracy [dB] over the frequency [Hz], according to embodiments of the disclosure.

FIG. 9 shows a table showing examples of measure accuracy in dB with the maximum positive error (Max. pos. error) and the maximum negative error (Max. neg. error) for the curves of FIG. 8.

FIG. 10 shows a schematic example of a measurement setup comprising a receiver and a device under test (DUT), according to embodiments of the disclosure.

FIGS. 11a, 11b, and 11c show examples of frequency responses with different phase offsets on the left hand side and comparisons of frequency responses with, and without the inventive averaging on the right hand side, according to embodiments of the disclosure.

### DETAILED DESCRIPTION

Reference will now be made in detail to embodiments, examples of which are illustrated in the accompanying drawings. While the disclosure will be described in conjunction with these embodiments, it should be understood that they are not intended to limit the disclosure to these embodiments. On the contrary, the disclosure is intended to cover alternatives, modifications, and equivalents, which may be included within the spirit and scope of the disclosure as defined by the appended claims. Furthermore, in the following detailed description, numerous specific details are set forth in order to provide a thorough understanding. However, it will be recognized by one of ordinary skill in the art that embodiments may be practiced without these specific details.

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present disclosure. However, it will be apparent to those skilled in the art that embodiments of the present disclosure may be practiced without these specific details. In other instances, well-known structures and devices are shown in block diagram form rather than in detail in order to avoid obscuring embodiments of the present disclosure. In addition, features of the different embodiments described herein after may be combined with each other, unless specifically noted otherwise.

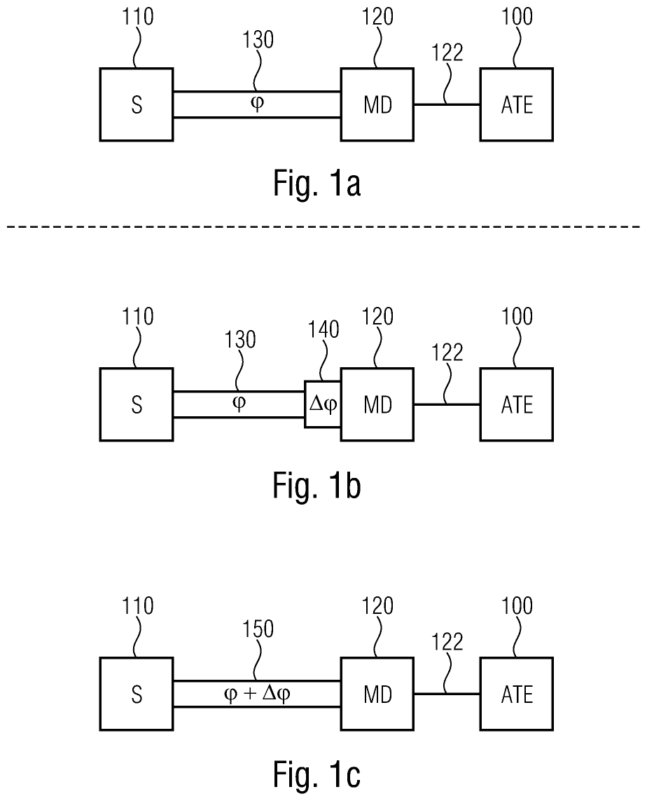

FIG. 1a shows a schematic view of an automated test equipment for mitigating an influence of a mismatch loss in a measurement setup, according to embodiments of the disclosure. FIG. 1a shows an automated test equipment (ATE) 100, a source (S) 110 and a measurement device (MD) 120.

In situation a) (as shown in FIG. 1a) the signal source 110 is connected to the measurement device 120 via a first transmission line 130. The transmission line may enable signal propagation from the signal source 110 to the measurement device 120. Signal source 110 may provide a first signal comprising a first frequency for the measurement device 120. Transmission line 130 may cause a phase shift φ, e.g. a signal delay in the first signal. As an example, in this situation or configuration of the measurement setup, the measurement device 120 may perform a first measurement, receiving the signal from the signal source 110 comprising the first frequency. The measurement device 130 may measure an amplitude or, for example a power of the incoming signal.

Furthermore, a second measurement may be performed, as shown in FIG. 1b. For the second measurement, signal source 110 may provide the first signal comprising the first frequency. Situation b) (as shown in FIGS. 1b and 1c) may show alternative arrangements of the measurement setup for performing the second measurement.

As shown in FIG. 1b the signal source 110 may be coupled to the measurement device 120 via the first transmission line 130 and a phase shifting device 140. The phase shifting device 140 may induce an additional phase shift Δφ, in addition to the phase shift φ caused by the first transmission line 130. It is to be noted, that situation b) may be used to perform the first measurement as well. Hence, for the first measurement Δφ may be set to a first value Δφ₁, e.g. Δφᵢ=0. For the second measurement, Δφ may be changed to a second value Δφ₂.

As shown in FIG. 1c, for example alternatively, the signal source 110 may be coupled to the measurement device 120 via a second transmission line 150, wherein the second transmission line may cause a phase shift φ+Δφ in the first signal provided by source 110.

Therefore a phase offset, e.g. a phase offset Δφ or a phase offset Δφ₂−Δφ₁ may be present for the second measurement in comparison to the first measurement.

Hence, a desirable phase offset, e.g. a phase offset of approximately 90° may be induced, and exploited according to the disclosure in order to mitigate mismatch losses, for example caused by a moderate matching of signal source 110 and measurement device 120.

Hence, the automated test equipment 100 may receive the measurement results 122 form the measurement device 120 and may be configured to average the first and second measurement result, received from the measurement device 120, in order to determine or obtain a processed measurement result. The measurement result may, for example, be an amplitude, or a power, e.g. a power of the signal received by the measurement device 120, for example a scalar measurement result, in which an influence of a mismatch loss, e.g. caused by a mismatch between signal source 110 and measurement device 120, may be mitigated.

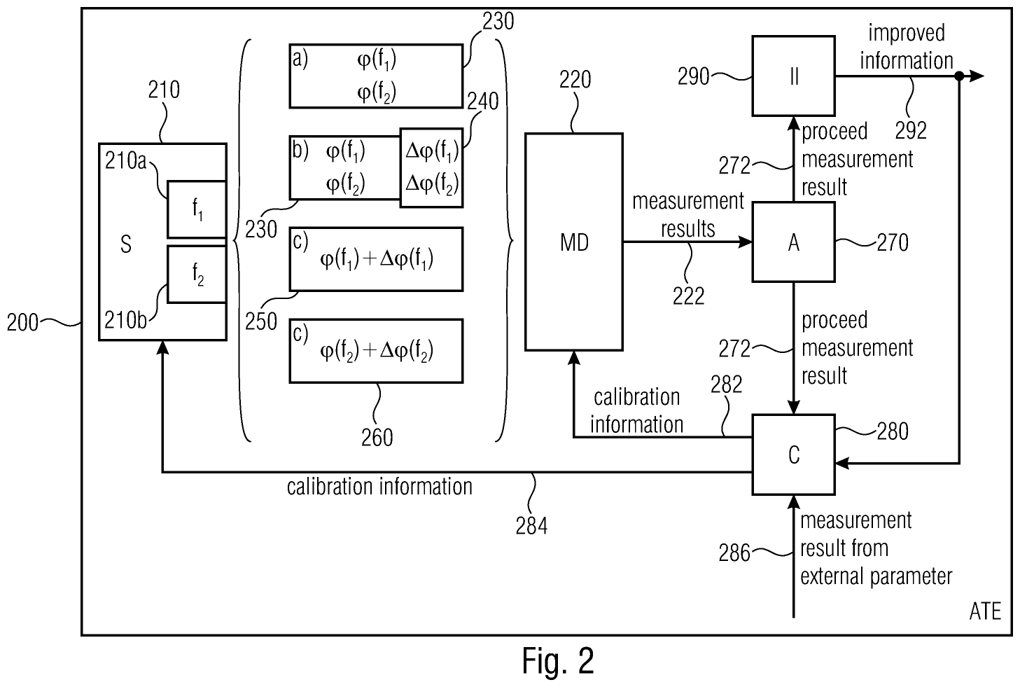

FIG. 2 shows a schematic view of an automated test equipment for mitigating an influence of a mismatch loss in a measurement setup with additional, optional features, according to embodiments of the disclosure. FIG. 2 shows an automated test equipment (ATE) 200 comprising a signal source (S) 210 and a measurement device (MD) 220. Signal source 210 may be configured to provide a first signal with a first frequency f₁, for example using first signal provider 210a. In addition, source 201 may be configured to provide at least a second signal with a second frequency f₂, for example using second signal provider 210b. The first frequency f₁ and the second frequency f₂ may be different. The automated test equipment may comprise at least one transmission line, and may comprise, in addition, a phase shifting device. The brackets {⋅} in FIG. 2 show different options for a coupling of the signal source 210 and the measurement device 220. The automated test equipment may comprise any or none of the transmission lines and/or the phase shifting device, or an arbitrary combination thereof.

As an optional feature, the automated test equipment 200, as shown in FIG. 2 may comprise a first transmission line 230. The first transmission line may cause or induce a phase shift φ(f₁) between the signal source 210 and the measurement device 220 for the first signal with frequency f₁ and may cause or induce a phase shift φ(f₂) between the signal source 210 and the measurement device 220 for the second signal with frequency f₂. Transmission line 230 may be used for a coupling of the signal source 210 and the measurement device 220 in order to perform the first measurement based on the first signal comprising the first frequency e.g. as explained in FIG. 1a.

This setup, with a coupling of signal source 210 and measurement device 220 with transmission line 230, may, in addition, be used in order to perform a third measurement, while the signal source 210 provides the second signal with the second frequency f₂ inducing the phase shift φ(f₂) between the signal source 210 and the measurement device 220.

As another optional feature, the automated test equipment 200 may comprise a phase shifting device 240. The phase shifting device 240 may be configured to induce or cause a phase shift Δφ(f₁) between the signal source 210 and the measurement device 220 for the first signal with frequency f₁ and may cause or induce a phase shift Δφ(f₂) between the signal source 210 and the measurement device 220 for the first signal with frequency f₂.

Phase shifting device 240 may be used in combination with transmission line 230 for a coupling of the signal source 210 and the measurement device 220, in order to perform the second measurement based on the first signal comprising the first frequency f₁, e.g. as explained in FIG. 1b, inducing or causing inducing a phase shift for the first signal of φ(f₁)+Δφ(f₁).

This setup with a coupling of signal source 210 and measurement device 220 with phase shifting device 240 and transmission line 230 may, in addition, be used in order to perform a fourth measurement, while the signal source 210 provides the second signal with the second frequency f₂, hence inducing a phase shift for the second signal of φ(f₂)+Δφ(f₂).

As another optional feature, the automated test equipment 200 may comprise a second transmission line 250 and/or a third transmission line 260. As an example, the second transmission line 250 may be configured to induce or cause a phase shift φ(f₁)+Δφ(f₁) between the signal source 210 and the measurement device 220 for the first signal with frequency f₁ and the third transmission line 260 may be configured to induce or cause a phase shift φ(f₂)+Δφ(f₂) between the source 210 and the measurement device 220 for the second signal with frequency f₂.

Furthermore, automated test equipment 200 comprises an averaging unit (A) 270. Averaging unit 270 may be configured to receive measurement results 222 from the measurement device, for example a result from the first measurement and a result from the second measurement as explained before, in order to obtain or determine or calculate a processed measurement result 272. Hence, the automated test equipment 200 may be configured to average a plurality of pairs of measurement results comprising a phase offset, for different signals comprising different frequencies.

As an example for two signals with frequencies f₁ and f₂ respectively, a first measurement may be taken by the measurement device 220 when the signal source 210 and the measurement device 220 are coupled with the first transmission line 230, while the signal source 210 provides the first signal comprising the first frequency f₁.

A third measurement may be taken by the measurement device 220 when the signal source 210 and the measurement device 220 are coupled with the first transmission line 230, while the signal source 210 provides the second signal comprising the second frequency f₂.

Hence, the first measurement result may comprise a phase shift φ(f₁) and the third measurement result may comprise a phase shift φ(f₂).

In order to perform further measurements, the transmission line may be changed. In order to induce a desirable phase offset between two measurements to be averaged, phase shifting device 240 may be used, or transmission lines, e.g. transmission lines 250 and 260, may be used. Hence, a second measurement may be performed when the signal source 210 provides the first signal with the first frequency f₁ when the source 210 and the measurement device 220 are coupled with the first transmission line 230 and the phase shifting device 240 or with transmission line 250, in order to provide a e.g. desirable phase shift of φ(f₁)+Δφ(f₁), in order to provide a e.g. desirable phase offset of φ(f₁)+Δφ(f₁)−φ(f₁)=Δφ(f₁) between the first and second measurement at frequency of which the results are to be averaged in averaging unit 270.

In the same way, a fourth measurement may be performed when the signal source 210 provides the second signal with the second frequency f₂ and when the source 210 and the measurement device 220 are coupled with the first transmission line 230 and the phase shifting device 240 or with transmission line 260, in order to provide a e.g. desirable phase shift of φ(f₂)+Δφ(f₂), in order to provide a e.g. desirable phase offset of Δφ(f₂) between the third and fourth measurement result at frequency f₂, of which the results are to be averaged in averaging unit 270.

As explained in the context of FIGS. 1a-1c, for the first and third measurement, the signal source 210 and the measurement device 220 may, for example, be coupled with the first transmission line 230 and the phase shifting device 240. In order to induce a desirable phase offset for the respective signal, the phase shifting device may be configured to change its offset. As a simple example, for the first and third measurement, the phase shifting device 240 may induce a phase shift of Δφ(f₁)=Δφ(f₂)=0.

It is to be noted, that for the signal comprising the second frequency f₂, for the fourth measurement, transmission line 250 may be used as well. On the one hand, only one of the phase offsets Δφ(f₁), Δφ(f₂) may be chosen arbitrarily with the distinct choice of transmission line 250. However, using only two transmission lines instead of three, in case no phase shifting device 240 is used, e.g. using transmission line 230 and transmission line 250, may allow to implement the measurement system with low costs. A good compromise for the choice of Δφ(f₁), Δφ(f₂), as well as e.g. choice of frequencies used and phase offsets desirable for said frequencies, may allow for a good mitigation of mismatch errors, even though choice of phase offsets may not be perfect for each distinct frequency used, but with lower time and cost effort, since less transmission lines may be changed and needed.

As another optional feature, the automated test equipment 200 may be configured to change between a usage of the different transmission lines 230-260 or between a usage of the (one or more) transmission lines and (one or more) transmission lines with phase shifting device 240. In addition, the automated test equipment 200 may optionally be configured to manipulate or adjust the phase shifting device 240, in order to induce the phase offset Δφ (e.g. a desired phase offset, or a phase offset which is sufficiently close to a desired phase offset), at least for the first signal comprising the first frequency. For example, the phase shifting device may be configured to provide a desired phase offset (or a phase offset which is sufficiently close to the desired phase offset) for a plurality of frequencies for which measurements are performed or over a certain relevant frequency range. Alternatively, the phase shifting device may be configured to adapt to respective frequencies for which the measurement is performed (e.g. such that the desired phase shift, or a phase shift sufficiently close to the desired phase shift is achieved for the currently measured signal).

As another optional feature, the automated test equipment may comprise a calibration unit (C) 280, configured to determine a calibration information 282 for the measurement device 220 based on the processed measurement result 271, e.g. based on the averaging of the first measurement result and the second measurement result, and for example on averaging of other measurement pairs with phase offsets at other frequencies.

As another optional feature, the automated test equipment 200 may be configured to use the calibration information 282 to calibrate or self-calibrate the measurement device 220. As shown as an example in FIG. 2 calibration information 282 may be provided to the measurement device 220, for example using calibration unit 280, in order to correct measurements performed by the measurement device 220.

Optionally the automated test equipment may be configured to calibrate the signal source 210, for example using the calibration unit 280. As an optional feature, as shown in FIG. 2, the calibration unit may therefore provide a calibration information 284 to the signal source 210. Calibration may be performed based on, and/or using, a measurement result 286 from an external power meter, before performing the self-calibration of the measurement device 220. Optionally, calibration of the signal source 210 may be performed based on the processed measurement result 272.

As another optional feature, the automated test equipment 200 may comprise an information improvement unit (II) 290. The automated test equipment 200 may be configured to determine, for example using information improvement unit 290 an improved information 292 about the signal provided by the signal source 210, for example the first signal comprising the first frequency f₁ based on the processed measurement result 272, e.g. based on the averaging of two measurements, e.g. for the first signal the averaging of the first measurement result and the second measurement result.

Optionally, the signal source 210 may be a device under test. The device under test may, as an example, only be configured to provide a signal with a first frequency in comparison to the signal source 210 shown in FIG. 2. Anyways, the automated test equipment 200 may be configured to determine the output power of the device under test, for example, based on the processed measurement result 272, e.g. based on the averaging of the first measurement result and the second measurement result, for example using averaging unit 270.

Therefore, the first measurement may be performed, as explained before, with the first transmission line 230, or as an optional example with the first transmission line 230 and the phase shifting device 240, e.g. with Δφ=0, coupled to the device under test and to the measurement device 220. The second measurement may be performed, as explained before, when the first transmission line 230 and the phase shifting device 240, e.g. with Δφ=Δφ_{desirable}, or when second transmission line 250, e.g. in case the first signal with the first frequency is provided by the device under test, or when the third transmission line 260, e.g. in case the second signal with the second frequency is provided by the device under test, is coupled with the device under test and the measurement device 220. The output power of the device under test may be measured using the measurement device 220 and the measured output power may be determined with increased accuracy, e.g. based on the averaging the measurement results.

As another optional feature, the phase offset Δφ, e.g. Δφ(f₁) and/or Δφ(f₂), may be 90° with a tolerance of +/−5° or +/−10° or +/−20° or +/−30°.

As another optional feature, the phase offset Δφ, e.g. Δφ(f₁) and/or Δφ(f₂), may be larger than 15°, or larger than 30°, or larger than 45°, or larger than 60°.

As explained before, phase offsets may be dependent on the frequency of the signal. For example, especially in case the same transmission line is used for measurements at different frequencies with phase offsets, the phase offsets may not be equal but may rather be in an interval. Hence, the number of transmission lines needed and the number of transmission line switches may be reduced, wherein the phase offsets, being in a desirable or advantageous interval may allow for a good mitigation of mismatch errors.

As another optional feature, the automated test equipment 200 may be configured to determine a calibration information 282, for example using calibration unit 280, for the measurement device 220 based on the processed measurement result 272, e.g. based on an averaging of the first measurement result and the second measurement result and based on an averaging of the third measurement result and the fourth measurement result.

Alternatively or in addition, the automated test equipment 200 may be configured to determine an improved information 292, e.g. using information improvement unit 290, about the output power of the signal source 210 based on the processed measurement result 272, e.g. based on the averaging of the first measurement result and the second measurement result and based on the averaging of the third measurement result and the fourth measurement result.

In general, as another optional feature, the improved information 292 may be used in order to determine a calibration information, for example, for the measurement device 220 and/or the signal source 210, e.g. using calibration unit 280.

In addition, in general it is to be noted that measurements, averaging, calibration information determination and information improvement, as explained in the context of a first and a second signal comprising a first and second frequency may be performed accordingly for any number of signals comprising different frequencies.

As an example, the signal source 210 may be configured to provide a signal comprising a plurality of different frequencies for the measurement device 220. The automated test equipment may be configured to perform a plurality of averaging, e.g. using averaging unit 270, between a plurality of first measurement results of a plurality of first measurements and a plurality of second measurement results of a plurality of second measurements.

Optionally, in order to perform a large number of measurements with a phase offset, a phase shifting device 240 may be used, e.g. such that the phase offset Δφ is adjusted for each measurement, e.g. with respect to the specific frequency of the signal provided by the signal source 210.

Hence, the first measurements may be performed for different frequencies when the signal source 210, while providing the signal for the measurement device 220, and the measurement device are coupled with the first transmission line 230, or as an example, with the first transmission line 230 and the phase shifting device 240, e.g. with Δφ=0.

The plurality of second measurements may be performed for the different frequencies when the signal source 210, while providing the signal for the measurement device, and the measurement device are coupled with the transmission line and a phase shifting device, e.g. with Δφ=Δφ(f)≠0, wherein the phase shifting device is configured to induce phase shifts to the signal for the plurality of frequencies of the signal.

Furthermore, the plurality of second measurements may be performed, such that for each second measurement of the plurality of second measurements the signal comprises a respective phase shift between the signal source 210 and the measurement device 220, induced by the phase shifting device 240, such that the respective phase shifts differ by respective phase offsets Δφ between the second measurements and corresponding first measurements.

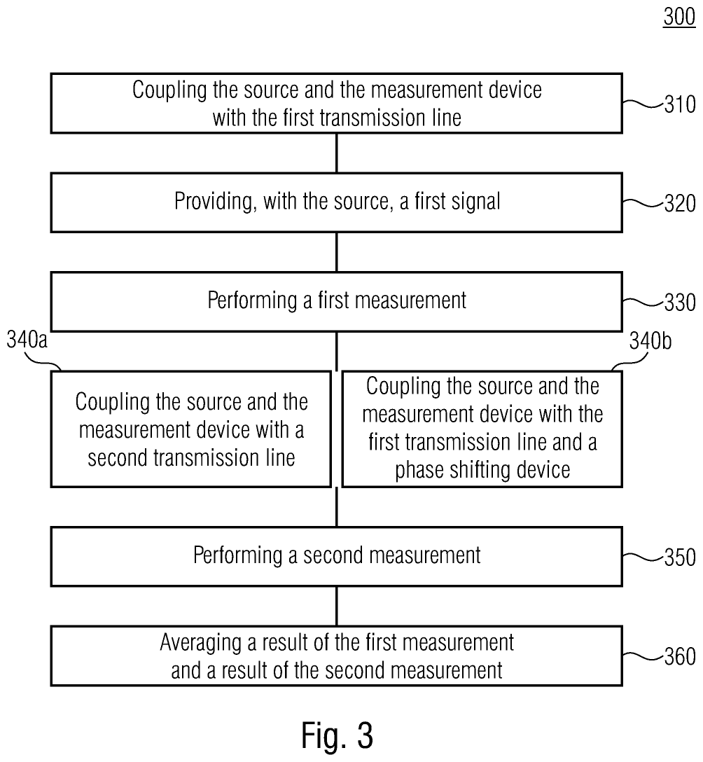

FIG. 3 shows a block diagram of a method for mitigating an influence of a mismatch loss in a measurement setup, according to embodiments of the disclosure. The measurement setup may comprise a source, a measurement device and a first transmission line. Method 300 shown in FIG. 3 comprises coupling 310 the source and the measurement device with the first transmission line, providing 320, with the signal source, a first signal comprising at least a first frequency for the measurement device, performing 330 a first measurement when the signal source, while providing the first signal for the measurement device, and the measurement device are coupled with the first transmission line, coupling 340a the source and the measurement device with a second transmission line, wherein the second transmission line is configured to induce a phase shift to the first signal at least for the first frequency of the signal, or coupling 340b the source and the measurement device with the first transmission line and a phase shifting device, wherein the phase shifting device is configured to induce a phase shift to the first signal at least for the first frequency of the signal, performing 350 a second measurement when the signal source, while providing the first signal for the measurement device, and the measurement device are coupled with the second transmission line, or with the first transmission line and the phase shifting device such that a phase shift between the source and the measurement device differs by a phase offset between the first measurement and the second measurement at least for the first frequency and averaging 360 a result of the first measurement and a result of the second measurement in order to obtain a processed measurement result.

In the following further embodiments and additional information for a better understanding of the disclosure is provided. Aspects, features and functionalities disclosed in the following may be used individually or in combination with any or all of the features and functionalities explained before. Some embodiments explained before may be explained again using different words.

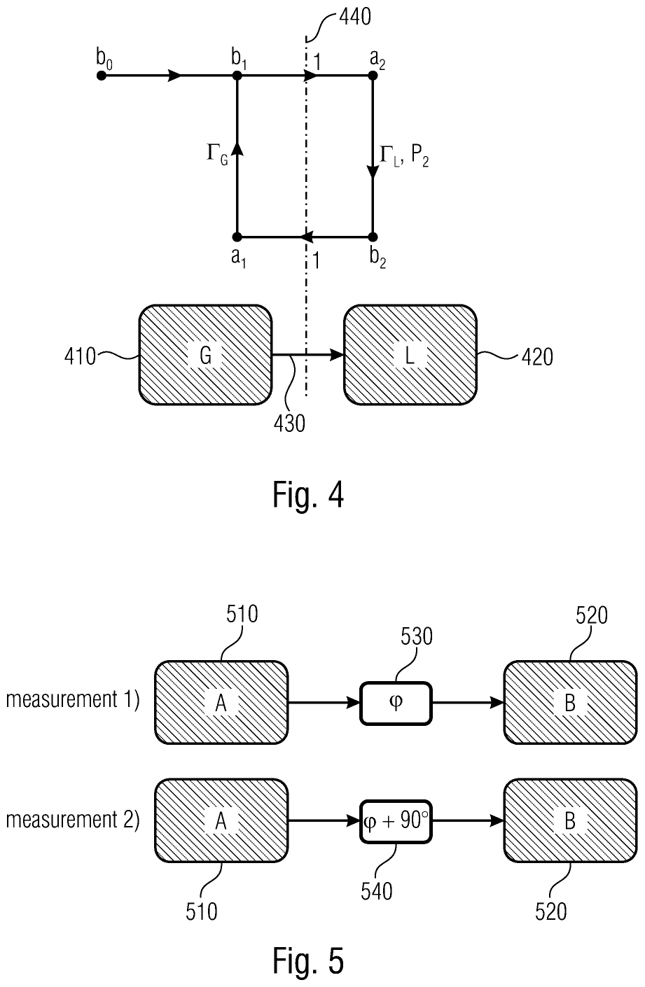

In the following situation, e.g. an initial situation, for example a situation that may be addressed with embodiments of the disclosure is presented and explained. Consider two RF components A and B connected together. The following FIG. 4 shows an example of a signal flow, or, as an example, describes the signal flow of this circuit with a lossless connection. P₂ equals the input power to the second component.

FIG. 4 shows a schematic example of a first RF (radio frequency) component and a second RF component connected together according to embodiments of the disclosure. The first component may be component A, e.g. as shown with block G 410, for example a source, and the second component may be component B, e.g. as shown with block L 420, for example a load. The components are coupled with a transmission line 430.

aᵢ, bᵢ, with i=1,2 are the complex amplitudes of the reflected waves and the incident waves respectively. Γⱼ, with j=G, L is the reflection coefficient of the respective component.

Component 410 may be configured to provide a first wave b₀. Hence, as shown in FIG. 4 the input power to the second component 420 may be

$${P}_{2} = {\vert {a}_{2} \vert}^{2} - {\vert {b}_{2} \vert}^{2}$$

$${a}_{2} = {b}_{1} = {b}_{0} + {Γ}_{G} \cdot {Γ}_{L} \cdot {a}_{2}$$

$${a}_{2} = \frac{{b}_{0}}{1 - {Γ}_{G} \cdot {Γ}_{L}}$$

$${b}_{2} = {a}_{2} \cdot {Γ}_{L}$$

$${P}_{2} = {\vert {b}_{0} \vert}^{2} \frac{1 - {\vert {Γ}_{L} \vert}^{2}}{{\vert 1 - {Γ}_{G} \cdot {Γ}_{L} \vert}^{2}}$$

The power at the input of the second component P₂ is affected by the reflection coefficients Γ_{G} and Γ_{L}. This effect is called mismatch loss ML.

$$ML = \frac{1 - {\vert {Γ}_{L} \vert}^{2}}{{\vert 1 - {Γ}_{G} \cdot {Γ}_{L} \vert}^{2}}$$

The transmission line 430 may, for example, be an ideal transmission line, such that a₂=b₁ and a₁=b₂. The dotted line 440 may show the signal transition between components 410 and 420.

Considering the reflection coefficients Γ_{G} and Γ_{L} are >0, they may have or, for example even have a significant impact on the frequency response of the two connected components. The range of a reflection coefficient is 0 . . . ±1. A reflection coefficient of the value ±1 corresponds to a total reflection, while 0 is a perfect matching.

The numerator of the mismatch loss 1−|Γ_{L}|² corresponds to a single reflection and can be predicted by a scalar frequency response measurement.

The denominator |1−Γ_{G}·Γ_{L}|² corresponds to the effect of multiple reflections between the two components. The reflection coefficients are complex values, consisting of magnitude and phase. As in usual applications the reflection coefficients are unknown, their influence on the frequency response is called mismatch uncertainty U_{ML}.

$${U}_{M L} = \frac{1}{{\vert 1 - {Γ}_{G} \cdot {Γ}_{L} \vert}^{2}}$$

Due to the random phase relation between the reflection coefficients, the term uncertainty limits is introduced. It describes the range of the possible mismatch error:

Uncertainty Limits (dB)=20 log|1±Γ_{G}·Γ_{L}|

For example, based on this initial situation, operation of, for example embodiments, of the disclosure may be performed as explained in the following.

In a summary, embodiments according to this disclosure, and/or for example the disclosure, are based on mitigating the influence of the phase relation between the reflection coefficients. This may minimize or even minimizes the residual mismatch error.

To do so, two measurements may, or for example must, be executed.

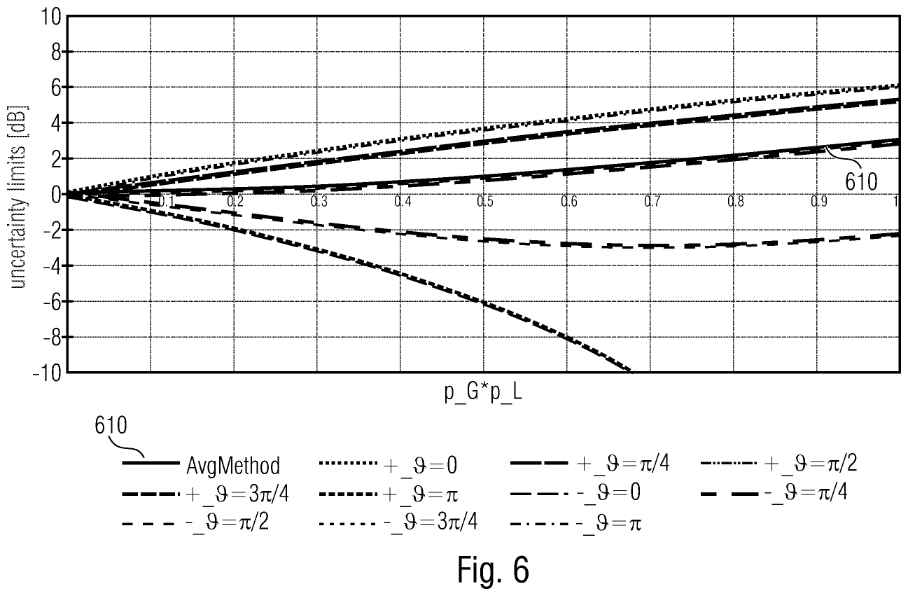

FIG. 5 shows a schematic example of two measurement setups that may be used to perform the first and second measurement according to embodiments of the disclosure. FIG. 5 shows a first component (A) 510, e.g. a signal source and a second component (B) 520, e.g. signal sink, e.g. a measurement device.

The first setup shown at the top of FIG. 5 (Measurement 1) may be used in order to perform the first measurement. Components 510 and 520 are coupled with a first transmission line 530, wherein the first transmission line 530 causes or induces a phase shift φ for a first signal, e.g. comprising a first frequency, provided by the component 510 for the component 530.

The second setup shown at the bottom of FIG. 5 (Measurement 2) may be used in order to perform the second measurement. Components 510 and 520 are coupled with a different transmission line 540, e.g. a transmission line comprising transmission line 530 and a phase shifting device, wherein transmission line 540 causes or induces a phase shift of (ρ+90° for a first signal, e.g. comprising a first frequency, provided by the component 510 for the component 530.

As explained before, a phase shifting device may only induce a phase offset that may be approximately 90°.

This may, for example be performed or may for example be valid, assuming the frequency response of the phase shifting device is neglectable or known, or for example, assuming the frequency response of the phase shifting device is neglectable or known.

As an example, an estimation of the frequency response of the phase shifting device may be taken into consideration for the phase offset provided by the phase shifting device as well.

As an example, the effect of the inventive averaging may be explained in further detail in the following.

The average of both frequency responses may result, or for example even, results in a final frequency response of both components, e.g. with only minor or neglectable or reduced, or for example even without any, influence of the phase relation between the reflection coefficients of the components. This can be shown be the calculation of the resulting mismatch uncertainty limits:

For simplification, the logarithm is disregarded at first.

$$\vert 1 \pm {Γ}_{G} \cdot {Γ}_{L} \vert = \vert 1 \pm {ρ}_{G} {e}^{{j}_{{φ}_{G}}} {ρ}_{L} {e}^{{j}_{{φ}_{L}}} \vert$$

(wherein Γᵢ=ρᵢe^{jφi} may, for example, be the complex reflection factors, for i=G, L with amplitude ρᵢ and phase φᵢ)

$$= \vert 1 \pm {ρ}_{G} {ρ}_{L} {e}^{j ( {φ}_{G} + {φ}_{L} )} \vert$$

$$= \vert 1 \pm {ρ}_{G} {ρ}_{L} cos ( {φ}_{G} + {φ}_{L} ) - j {ρ}_{G} {ρ}_{L} sin ( {φ}_{G} + {φ}_{L} ) \vert$$

$$= \sqrt{{( 1 \pm {ρ}_{G} {ρ}_{L} cos ( {φ}_{G} + {φ}_{L} ) )}^{2} + {ρ}_{G}^{2} {ρ}_{L}^{2} {sin}^{2} ( {φ}_{G} + {φ}_{L} )}$$

For a better overview, in the following, the square root is disregarded as well, and one may consider the term

(1±ρ_{G}ρ_{L} cos(φ_{G}+φ_{L}))²+ρ_{G}²ρ_{L}² sin²(φ_{G}+φ_{L}).

In order to simplify the formula the following expressions may be replaced

φ_{G}+φ_{L}=ϑ, ρ_{G}ρ_{L}=x

Hence, one may receive the terms

1±2x cos(ϑ)+x² cos²(ϑ)+x² sin²(ϑ)

1±2x cos(ε)+x²

Adding the 90° phase offset to ϑ, the mismatch uncertainty results to:

1±2x cos(ϑ+π)+x²

=1±2x(cos(ϑ)cos(π)−sin(ϑ)sin(π))+x²

1∓2x cos(ϑ)+x²

Averaging these two measurements, the uncertainty results to:

$$\frac{[ 1 \pm 2 x cos ( ϑ ) + {x}^{2} ] + [ 1 ∓ 2 x cos ( ϑ ) + {x}^{2} ]}{2} = 1 + {x}^{2}$$

Taking the logarithm and the square root in consideration again, the mismatch uncertainty limits may be expressed, e.g. in logarithmic form, as

$$20 \cdot {log}_{10} ( \sqrt{\frac{[ 1 \pm 2 x cos ( ϑ ) + {x}^{2} ] + [ 1 ∓ 2 x cos ( ϑ ) + {x}^{2} ]}{2}} = 20 \cdot {log}_{10} ( \sqrt{1 + {x}^{2}} ) .$$

Hence, as an example, the phase relation, represented by 0 may cancel out reducing the uncertainty and allowing for a precise calibration. It is to be noted that although the phase relation may not cancel out completely for phase offsets that are not exactly 90°, an improvement of measurement accuracy may still be achieve since the impact of the unknown phase relation may cancel out at least partially.

In other words and as an example, with regard to the above derivation, the limits in dB for the maximum error caused by mismatch may be expressed as

20 log|1+Γ_{G}·Γ_{L}|

20 log|1−Γ_{G}·Γ_{L}|.

It can be shown, e.g. with the above derivation, that using the inventive concept, e.g. an inventive method as described herein, for example for a reduction or for a decrease of an overcompensation at a receiver calibration, the phase relation of the backflow damping of the two components may not have or may only have to a limited e.g. to a small scope, an influence on the error. This may, for example in most cases, lead to a reduction of the error caused by mismatch.

As explained above, the logarithm may or should even be neglected at first. Furthermore, as explained above, for a calculation of the absolute value, temporally, the square root may be neglected. In addition, it is to be noted that Γ_{G} and Γ_{L} are complex numbers. As an example, the above shown derivate may be performed separately for the two terms 20 log|1+Γ_{G}·Γ_{L}| and 20 log|1−Γ_{G}·Γ_{L}|.

In the following further examples of the operation of the disclosure or of the advantages of the disclosure are explained.

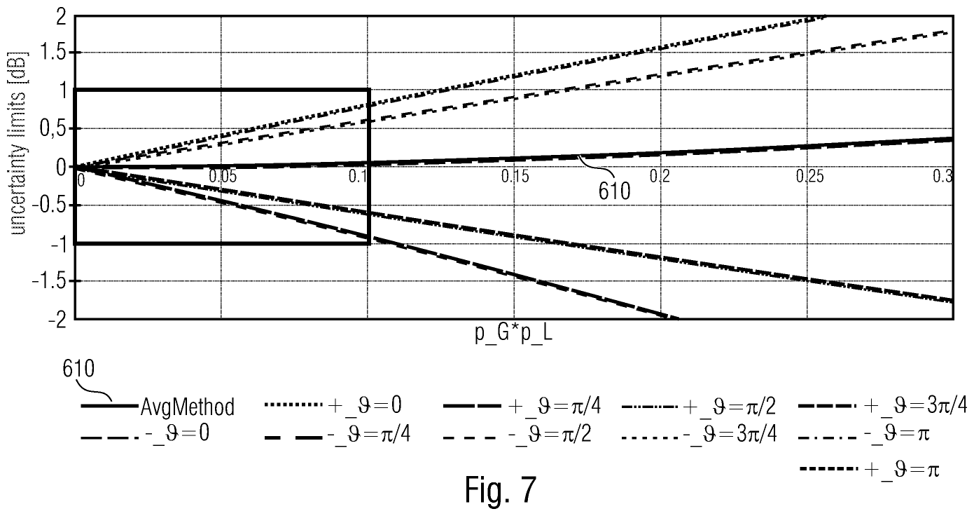

FIG. 6 shows an example of uncertainty limits in dB over different ρ_{G}ρ_{L} according to embodiments of the disclosure. Assuming different phase relations ϑ of ρ_{G} and ρ_{L} and determining the uncertainty limits for ρ_{G}ρ_{L}=0 . . . 1 may, for example be shown in FIG. 6. The bold black curve 610 shows the maximum mismatch error using the described methodology according to

20·log₁₀(\sqrt{1/x²}).

All other curves show a possible mismatch error without any compensation, e.g. without phase canceling according to

20·log₁₀(\sqrt{1±2x·cos(ϑ)+x²}).

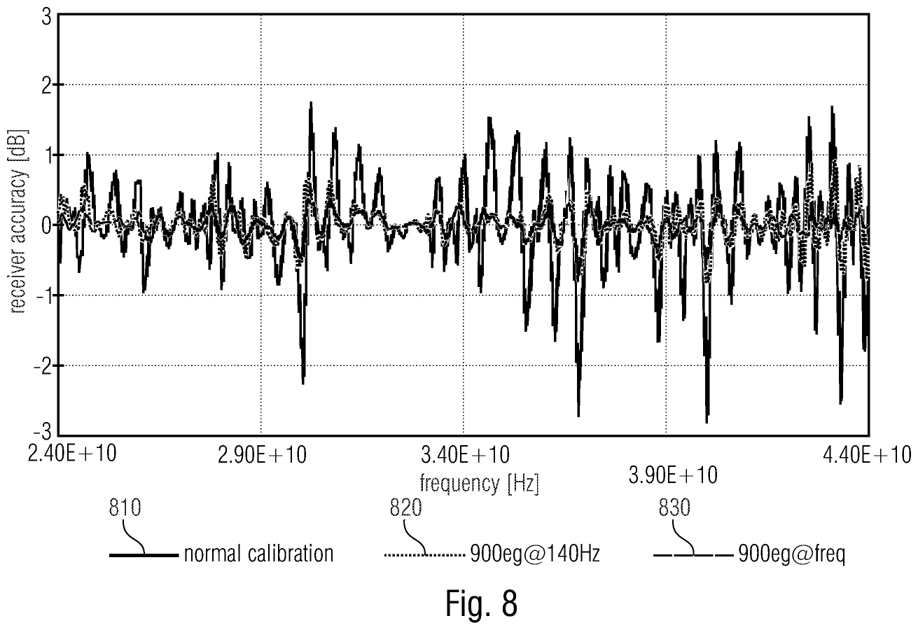

FIG. 7 shows a part of the example shown in FIG. 6, namely uncertainty limits in dB over the ρ_{G}ρ_{L} for ρ_{G}ρ_{L}=0 . . . 0.3.

With a return loss of RL_{G}=RL_{L}=−10 dB, which may for example be defined as

$$R L = 10 {log}_{10} ( \frac{{P}_{in}}{{P}_{ref}} ) ,$$

wherein Pᵢₙ is the incident power and P_{ref} is the reflected power, (e.g. in a mmWave measurement system) of the two connected components, the multiplication |ρ_{G}·ρ_{L}| results in |0.3162 0.3162|≈0.1. The remaining error using the described methodology is close to zero, while in applications without any mismatch error compensation, an error of ˜1.0 dB is possible.

Therefore, as shown in FIGS. 6 and 7 the uncertainty limits may be reduced significantly with the inventive averaging of the first and second measurement comprising the phase offset.

As an example, e.g. in order to sum up and underline the difference between the simplifications in the derivation and the results shown in FIGS. 6 and 7 it is to be noted, that no logarithm and no square root may, for example be included, inside the calculation. However, the plots (FIG. 6 and FIG. 7) show functions that are considering the square root and the logarithm. So the black curve (“AvgMethod”) is not 1+x², but it is: 20·log₁₀(\sqrt{1+x²}). Same for the other curves, but, of course, without phase cancelling: 20·log₁₀(\sqrt{1±2x·cos(ϑ)+x²}).

In the following a use case according to embodiments of the disclosure is explained in further detail. Use case: measure power calibration on WSMM

The measure path on WSMM is calibrated by the stim path, that has been calibrated before with a thermal power sensor. As the power sensor is well matched, the calibration is valid in a 50 Ohm system.

The matching of the stimulus and the measure may, for example be or is moderate. Therefore, connecting both together for calibration may implicate, or for example implicates a mismatch error. This error may, or for example even will, be part of the calibration data of the measurement path.

Connecting a well matched signal source to the measure path, it may, or for example will, show, that the measurement is inaccurate because of the calibration data including the mismatch error.

This error occurring during calibration can be mitigated by the phase offset methodology according to embodiments of the disclosure. The simulation (comprising, e.g. containing, measured data of WSMM components) shows, that the measure accuracy can be improved significantly using this method.

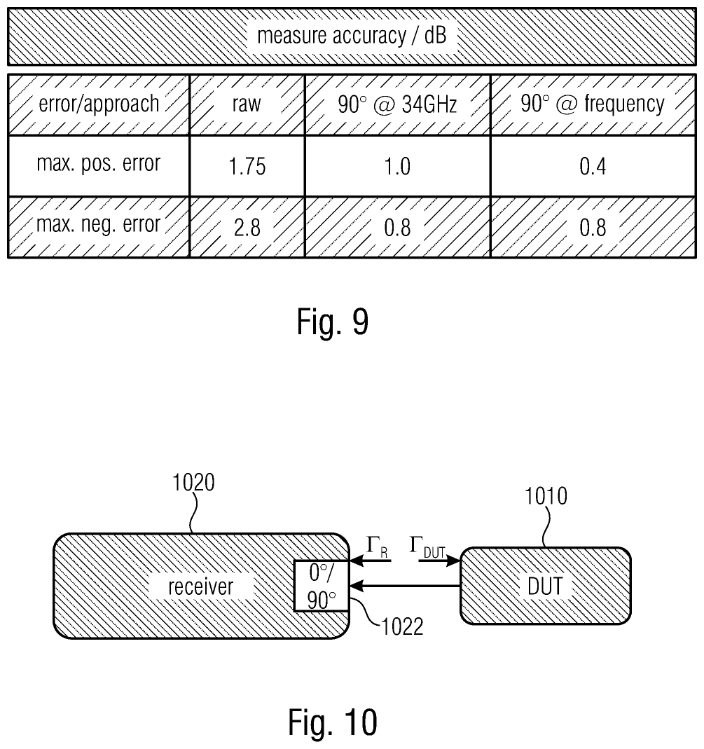

FIG. 8 shows an example of a receiver accuracy [dB] over the frequency [Hz], according to embodiments of the disclosure. The black curve 810 shows the raw measure accuracy. For the red curve 820, a 90° phase offset at a certain frequency (34 GHz) was used. The green curve 830 shows the accuracy, if the 90° phase offset is used over the whole frequency range.

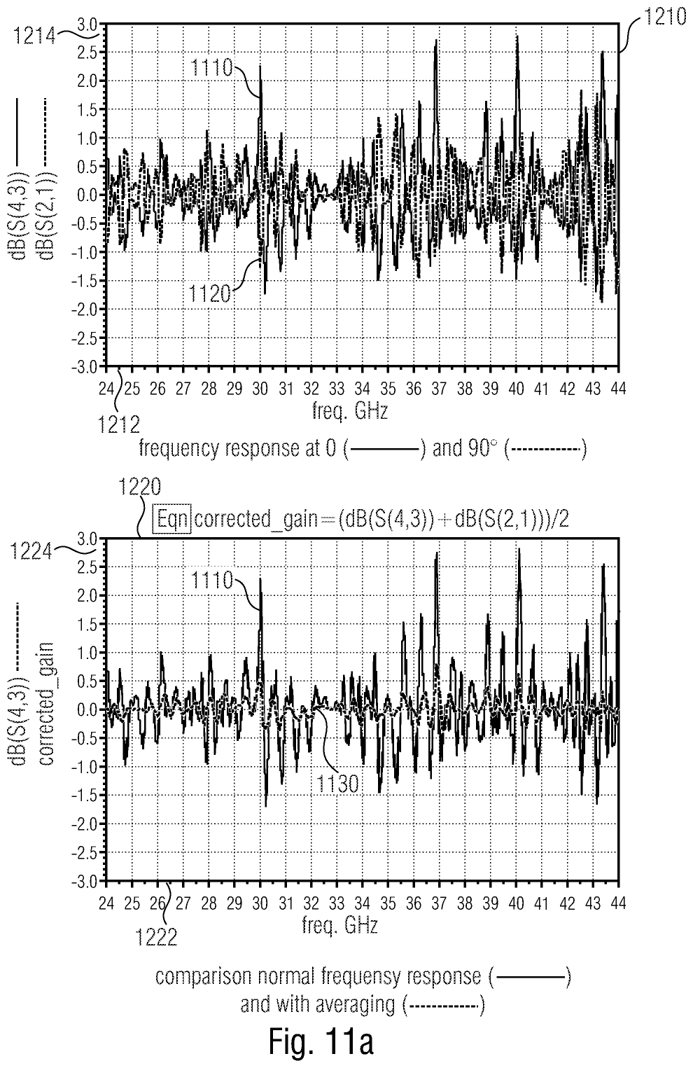

FIG. 9 shows a table showing examples of measure accuracy in dB with the maximum positive error (Max. pos. error) and the maximum negative error (Max. neg. error) for the three curves (raw measurement accuracy—raw, 90° phase offset at 34 GHz—90° @ 34 GHz, 90° phase offset is used over the whole frequency range—90° @ Frequency).

As an example, as shown, averaging of measurements according to the disclosure may provide a significant improvement of measurement accuracy, even if only performed at one frequency. Max. pos. error of 1.75 dB and max. neg. error of 2.8 dB of a, e.g. conventionally calibrated receiver may be reduced to 1.0 dB and 0.8 dB respectively as shown in FIG. 9. As can be seen with curve 830 and the last column of the table in FIG. 9, averaging over a plurality of frequencies may allow to further improve measurement accuracy. Hence, as explained before, averaging may be performed for more than one, or even a large number of frequencies.

Another use case for embodiments according to the disclosure may be a bad matched device under test.

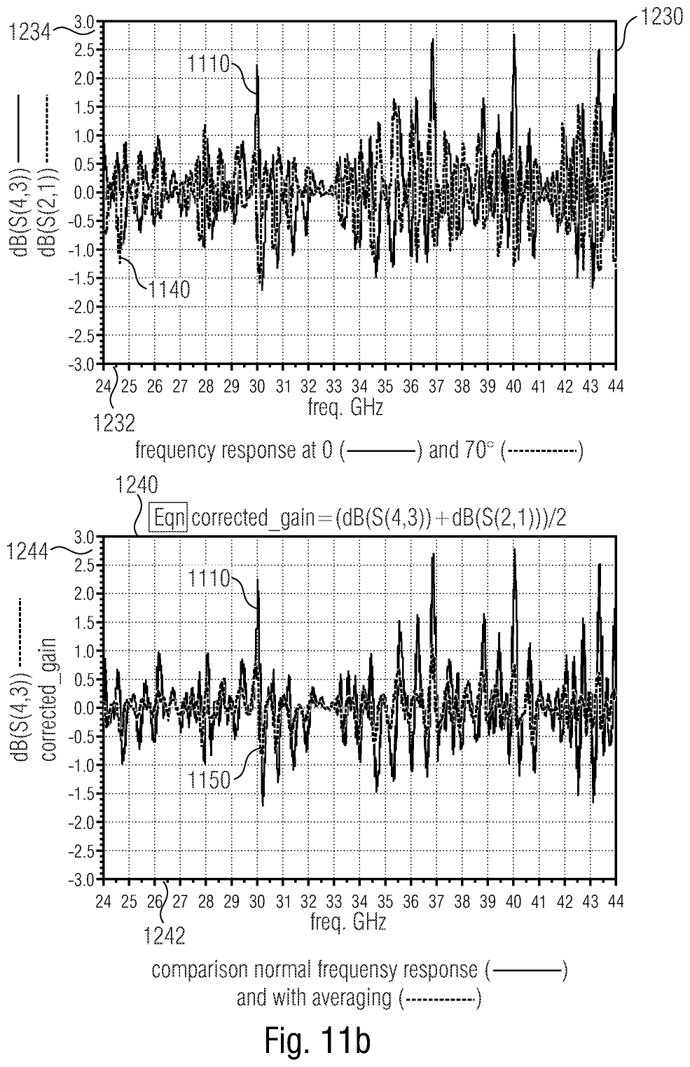

FIG. 10 shows a schematic example of a measurement setup comprising a receiver and a device under test (DUT), according to embodiments of the disclosure. FIG. 10 shows a schematic example of a receiver 1020, e.g. a measurement device and a device under test (DUT) 1010. The receiver may comprise a reflection coefficient Γ_{R}, the device under test may comprise a reflection coefficient Γ_{DUT} The receiver 1020, or for example a transmission line coupling the receiver 1020 and the device under test 1010, may comprise a phase shifting device 1022, configured to induce or cause a phase shift of 0° or of 90°.

Assuming the matching of the measurement system is moderate and also the device under test isn't well matched.

Even if the measure calibration of the measurement system is improved, once again a mismatch error occurs that cannot be predicted.

Also here, an additional 90° phase offset measurement may, or for example will, help to compensate for the mismatch error and determine much more accurately the output power of the device under test.

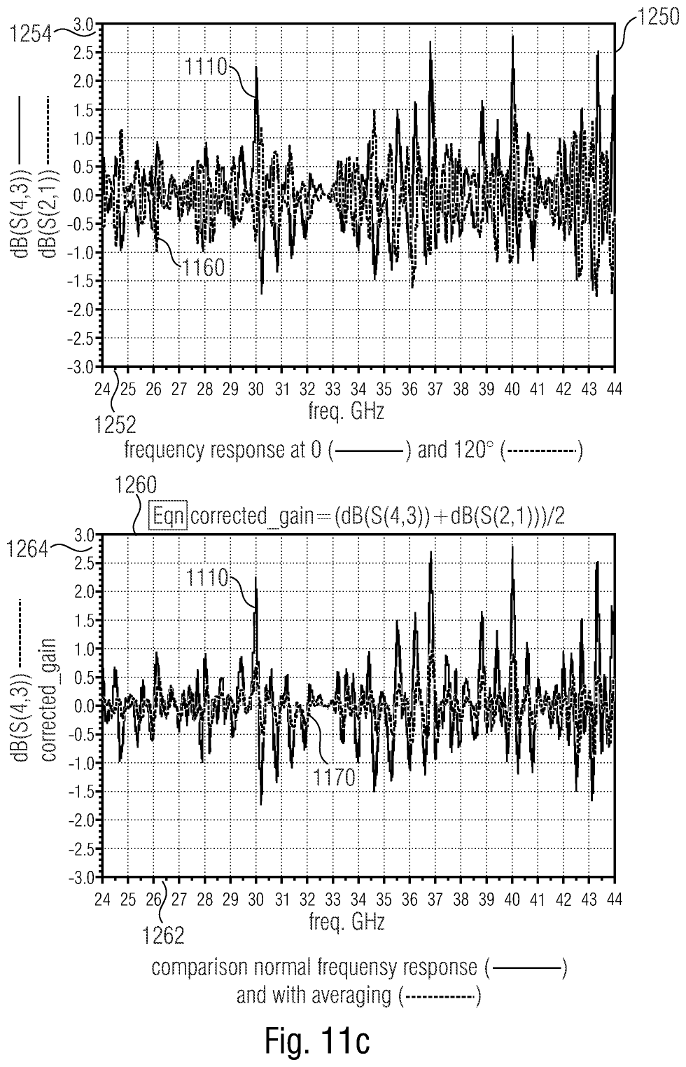

FIGS. 11a, 11b, and 11c, show examples of frequency responses with different phase offsets on the left hand side and comparisons of frequency responses with, and without the inventive averaging on the right hand side, according to embodiments of the disclosure.

The graphical representation 1210 on the left hand side of FIG. 11a shows frequency responses of two measurements made at phase shifts of 0 degrees and 90 degrees. An abscissa 1212 describes a frequency [e.g. in GHz] and an ordinate 1214 describes a frequency response (e.g. in the form of a deviation from an expected measurement value), e.g. in dB.

A first curve 1110 of graphical representation 1210 describes the frequency response measured at a (reference) phase shift or comprising a phase shift of 0 degree, and a second curve 1120 describes a frequency response measured at a (reference) phase shift or comprising a phase shift of 90° (e.g. relative to the reference phase shift).

These frequency responses may be the result of the first and second measurement, as explained before, and hence the phase offset (e.g. between the measurements) may be 90°.

On the right hand side of FIG. 11a, in graphical representation 1220 comprising abscissa 1222 describing a frequency [e.g. in GHz] and ordinate 1224 describing a frequency response (e.g. in the form of a deviation from an expected measurement value), e.g. in dB, the first frequency response 1110 is shown again, but in comparison to an averaged frequency response 1130, e.g. a corrected gain, that shows the average of the first frequency response 1110 and the second frequency response 1120, e.g. the sum of frequency responses 1110 and 1120 divided by two.

As an example, the peaks of frequency response 1110 may be caused by constructive interference in the case of the positive peaks and by destructive interference in the case of the negative peaks, e.g. caused by the unknown phase relation of the reflection coefficients. Hence, it may be difficult, as an example, to calibrate an output power of a device under test. For example, in case the phase relation of the reflections coefficients of device under test and measurement device (and/or the transmission line) causes constructive interference, the output power of the device under test may be assumed higher than it is in reality. As can be seen by averaged frequency response 1130, the averaging according to the disclosure mitigates the impact of the phase relation of the reflection coefficients significantly, allowing for an easier extraction of information, for example for a calibration of a device under test. By the inventive averaging some of the peaks of frequency response 1110 are reduced to a fraction of their amplitude, for example to a third or even to a fourth of their amplitude, hence allowing for improved measurement and/or calibration accuracy.

In FIGS. 11b and 11c further graphical representations are shown. The graphical representation 1230 on the left hand side of FIG. 11b shows frequency responses of two measurements made at phase shifts of 0 degrees and of 70 degrees, hence comprising a phase offset of 70 degrees. The graphical representation 1250 on the left hand side of FIG. 11c shows frequency responses of two measurements made at phase shifts of 0 degrees and of 120 degrees, hence comprising a phase offset of 120 degrees. Similar to FIG. 11a, abscissas 1232, 1252 describe frequencies [e.g. in GHz] and ordinates 1234, 1254 describe frequency responses (e.g. in the form of a deviation from an expected measurement value), e.g. in dB.

The frequency response made at phase shifts of 0 degrees in representations 1230 and 1250 is curve 1110 of graphical representation 1210 and describes, as explained before, the frequency response measured at a (reference) phase shift or comprising a phase shift of 0 degree.

In representation 1230 a third curve 1140 describes a frequency response measured at a (reference) phase shift or comprising a phase shift of 70° (e.g. relative to the reference phase shift), and in representation 1250 a fourth curve 1160 describes a frequency response measured at a (reference) phase shift or comprising a phase shift of 120° (e.g. relative to the reference phase shift).

On the right hand sides of FIGS. 11b and 11c, in graphical representations 1240 and 1260 with abscissas 1242, 1262 describing frequencies [e.g. in GHz] and ordinates 1244, 1264 describing frequency responses (e.g. in the form of a deviation from an expected measurement value), e.g. in dB, the respective averaged frequency responses 1150 and 1170 are shown in comparison to curve 1110. Frequency response 1150 may be the result of an averaging of frequency responses 1110 and 1140 and frequency response 1170 may be the result of an averaging of frequency responses 1110 and 1160, e.g. as a sum of the respective two frequency responses, divided by two.

As shown in FIGS. 11a, 11b, and 11c, the inventors recognized that it may not be necessary to induce a distinct phase offset between a first and a second measurement. Although a phase offset of 90° may be desirable, it can be seen from frequency responses 1150 and 1170 that phase offsets within a tolerance of 90° may as well improve measurement accuracy. As an example both frequency responses 1150 and 1170 comprise significantly mitigated peaks in comparison to curve 1110, hence improving measurement and for example calibration accuracy. Hence, it may not be possible, in principle, to specify a tolerance, e.g. phase tolerance. In theory, via the averaging of the two measurements, even at the smallest phase offsets, measurement accuracy may improve in a correspondingly small manner.

Anyways, in case a tolerance is necessary, e.g. necessary with respect to a certain accuracy improvement, a tolerance may, for example, be +/−20°. In other words, in an embodiment, the phase shift between the reference phase (associated with a first measurement) and a second phase (e.g. associated with a second measurement) is larger than (or equal to) 20 degrees. FIGS. 11a, 11b, and 11c may show the impact, e.g. the impact of the different phase offsets on the improvement of the measurement accuracy.

In addition, in both cases (0° and 90+−x°) the amplitude response (without mismatch uncertainty) should be, or for example even must be, known. More specifically, it, e.g. the amplitude response, should, or for example even must, be known in the case 0°, and should differ, or for example even must be differing in the case 90+−x° minimally at most. As an example, the amplitude response of the case 90°+/−x° may be estimable or calculatable or similar to the amplitude response of the case 0°. In the plots of FIGS. 11a, 11b, and 11c, the amplitude response is not included, hence only the impact of the mismatch uncertainty is visible.

In addition, it is to be noted that the first frequency response comprising a phase shift of 0° may only be understood as an example. A persons skilled in the art will be well aware of the fact that it may be important for improved measurements, to provide a phase offset in between first and second measurement, hence, in general, signals with y° phase shift and y°+/−90°+/−x phase shift may be averaged.

Furthermore, it is to be noted, that as explained before, the averaging may, for example, be a weighted averaging, in other words, the averaging may be weighted. As an example, in a default averaging, the weights may all be equal to one, e.g. performing a normal averaging. However differing weight values may also be chosen.

Mismatch error is a severe issue for power accuracy, especially in millimeter wave applications, because good matching for very high frequency and broadband devices is hard to achieve.

Embodiments according to the disclosure mitigate the mismatch error in power accuracy measurements, e.g. to an absolute minimum, without the drawback of additional components (e.g. attenuators) like reduced power and additional uncertainty due to their limited rf performance.

It is applicable for internal calibration routines such as measure calibration in a stimulus measure loop back (and may therefore, for example, be used to achieve a good specification of an automated test equipment, e.g. using a self-calibration) and/or DUT measure applications, especially for bad matched devices and/or measure ports.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Depending on certain implementation requirements, embodiments of the disclosure can be implemented in hardware or in software. The implementation can be performed using a digital storage medium, for example a floppy disk, a DVD, a CD, a ROM, a PROM, an EPROM, an EEPROM or a ΓLASH memory, having electronically readable control signals stored thereon, which cooperate (or are capable of cooperating) with a programmable computer system such that the respective method is performed.

Some embodiments according to the disclosure comprise a data carrier having electronically readable control signals, which are capable of cooperating with a programmable computer system, such that one of the methods described herein is performed.

Generally, embodiments of the present disclosure can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, in one embodiment, the methods may be performed by any hardware apparatus.

The above described embodiments are merely illustrative for the principles of the present disclosure. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

The foregoing descriptions of specific embodiments have been presented for purposes of illustration and description. They are not intended to be exhaustive or to limit the disclosure to the precise forms disclosed, and many modifications and variations are possible in light of the above teaching. The embodiments were chosen and described in order to best explain the principles of the disclosure and its practical application, to thereby enable others skilled in the art to best utilize the disclosure and various embodiments with various modifications as are suited to the particular use contemplated. It is intended that the scope of the disclosure be defined by the Claims appended hereto and their equivalents.

What is claimed is:

1. An apparatus comprising:
at least one of at least one transmission line or a phase shifting device;
a measurement device operable to couple to a signal source via the at least transmission line to receive from the signal source a first signal comprising at least a first frequency, wherein the measurement device is operable to output a measurement result based on the received first signal, wherein the at least one transmission line and the phase shifting device are operable to induce a respective phase shift to the first signal; and
a measurement processing component operable to average a first measurement result and a second measurement result to generate a processed measurement result related to the first signal to mitigate an influence of a mismatch loss in a measurement setup environment,
wherein a phase shift between the signal source and the measurement device differs by a phase offset between the first measurement result and the second measurement result,
wherein the measurement device is operable to output the first measurement result in a first measurement setup comprising a first transmission line coupled between the measurement device and the signal source, and
wherein the measurement device is operable to output the second measurement result in a second measurement setup comprising at least one of the first transmission line and the phase shifting device coupled between the measurement device and the signal source or a second transmission line coupled between the measurement device and the signal source.

2. The apparatus of claim 1, wherein the measurement processing component is further operable to determine a calibration information for the measurement device based at least on the processed measurement result, and wherein the measurement processing component is further operable to determine a second calibration information for the signal source based at least on the processed measurement result and a received measurement result from an external power meter.

3. The apparatus of claim 2, further comprising an automated test equipment (ATE) comprising the signal source, the measurement device, and the measurement processing component; and
wherein the ATE is configured to use the calibration information to self-calibrate the measurement device.

4. The apparatus of claim 3, wherein the ATE is configured to calibrate the signal source using the second calibration information before the ATE performs a self-calibration of the measurement device.

5. The apparatus of claim 3, wherein the ATE further comprises the at least one transmission line and the phase shifting device, and wherein the ATE is configured to manipulate the phase shifting device to influence the phase offset.

6. The apparatus of claim 5, wherein the ATE is configured to determine an improved information concerning an output power of the signal source based at least on the processed measurement result.

7. The apparatus of claim 6, wherein the signal source comprises a device under test (DUT), wherein the ATE is configured to determine the output power of the DUT based at least on the processed measurement result,
wherein the ATE is configured to use the measurement device to determine the first measurement result of the output power of the DUT in the first measurement setup comprising the first transmission line coupled between the measurement device and the DUT,
wherein the ATE is configured to use the measurement device to determine the second measurement result of the output power of the DUT in the second measurement setup comprising at least one of the first transmission line and the phase shifting device coupled between the measurement device and the DUT or the second transmission line coupled between the measurement device and the DUT.

8. The apparatus of claim 1, wherein the phase offset comprises 90° with a tolerance of at least one of +/−5°, +/−10°, +/−20°, or +/−30°.

9. The apparatus of claim 1, wherein the phase offset comprises at least one of a value larger than 15°, a value larger than 30°, a value larger than 45°, or a value larger than 60°.

10. The apparatus of claim 7, wherein the signal source is operable to provide to the measurement device a second signal comprising at least a second frequency, wherein the second frequency is different from the first frequency, wherein the at least one transmission line and the phase shifting device are operable to induce respective phase shifts to the second signal,
wherein the measurement processing component is further operable to average a third measurement result and a fourth measurement result to generate a second processed measurement result related to the second signal,
wherein the phase shift between the signal source and the measurement device differs by a second phase offset between the third measurement result and the fourth measurement result,
wherein the measurement device is operable to output the third measurement result in the first measurement setup comprising the first transmission line coupled between the measurement device and the signal source, and
wherein the measurement device is operable to output the fourth measurement result in a third measurement setup comprising at least one of the first transmission line and the phase shifting device coupled between the measurement device and the signal source or a third transmission line coupled between the measurement device and the signal source.

11. The apparatus of claim 10, wherein the measurement processing component is further operable to determine the calibration information for the measurement device based at least on the processed measurement result and the second processed measurement result, wherein the ATE is configured to determine the improved information concerning the output power of the signal source based at least on the processed measurement result and the second processed measurement result.

12. The apparatus of claim 10, wherein the signal source is configured to provide to the measurement device a third signal comprising a plurality of different frequencies,
wherein the measurement processing component is operable to perform a plurality of averages between a plurality of first measurement results of a plurality of first measurements and a plurality of second measurement results of a plurality of second measurements to generate a plurality of processed measurement results related to the third signal,
wherein the measurement device is configured to perform the first measurements for the different frequencies in the first measurement setup comprising the first transmission line coupled between the measurement device and the signal source, and
wherein the measurement device is configured to perform the second measurements for the different frequencies in a third measurement setup comprising the first transmission line and the phase shifting device coupled between the measurement device and the signal source,
wherein the phase shifting device is configured to induce a corresponding phase shift to the third signal for a corresponding frequency of the plurality of frequencies of the third signal, and
wherein each respective phase shift between the signal source and the measurement device differs by a respective phase offset between a corresponding first measurement result and a corresponding second measurement result.

13. A method comprising:
using a first transmission line to couple a signal source and a measurement device;
providing to the measurement device by the signal source a first signal comprising at least a first frequency, wherein the measurement device is operable to output a measurement result based on the provided first signal;
performing a first measurement of the first signal to generate a first measurement result in a first measurement setup comprising the first transmission line coupled between the measurement device and the signal source;
performing a second measurement of the first signal to generate a second measurement result in a second measurement setup comprising at least one of the first transmission line and a phase shifting device coupled between the measurement device and the signal source or a second transmission line coupled between the measurement device and the signal source, wherein the first transmission line, the second transmission line, and the phase shifting device are configured to induce a respective phase shift to the first signal, wherein a phase shift between the signal source and the measurement device differs by a phase offset between the first measurement and the second measurement at least for the first frequency; and
averaging the first measurement result and the second measurement result to obtain a processed measurement result to mitigate an influence of a mismatch loss in a measurement setup environment.

14. The method of claim 13, further comprising:
determining a calibration information for the measurement device based at least on the processed measurement result.

15. The method of claim 14, further comprising:
using the calibration information to self-calibrate the measurement device.

16. The method of claim 15, further comprising:
receiving a measurement result from an external power meter; and
determining a second calibration information for the signal source based at least on the processed measurement result and the measurement result;
calibrating the signal source using the second calibration information before performing a self-calibration of the measurement device.

17. The method of claim 13, further comprising:
manipulating the phase shifting device to influence the phase offset.

18. The method of claim 13, further comprising:
determining an improved information concerning an output power of the signal source based at least on the processed measurement result.

19. The method of claim 13, wherein the signal source comprises a device under test (DUT).

20. A system comprising:
a measurement device operable to receive from a signal source a first signal comprising at least a first frequency;
a first transmission line operable to couple the signal source and the measurement device, wherein the measurement device is operable to output a measurement result based on the received first signal;
a second transmission line; and
a phase shifting device,
wherein the system is configured to average a first measurement result and a second measurement result to generate a processed measurement result related to the first signal to mitigate an influence of a mismatch loss in a measurement setup environment,
wherein the measurement device is operable to output the first measurement result in a first measurement setup comprising the first transmission line coupled between the measurement device and the signal source,
wherein the measurement device is operable to output the second measurement result in a second measurement setup comprising at least one of the first transmission line and the phase shifting device coupled between the measurement device and the signal source or the second transmission line coupled between the measurement device and the signal source, and
wherein a phase shift between the signal source and the measurement device differs by a phase offset between the first measurement result and the second measurement result at least for the first frequency of the first signal.
